(19) United States
(12) Patent Application Publication
(10) Pub. No.: US 2018/0226968 A1
(43) Pub. Date: Aug. 9, 2018

(54) Contention-Free Dynamic Logic

(71) Applicant: Advanced Micro Devices, Inc., Sunnyvale, CA (US)

(72) Inventor: Alexander W. Schaefer, Austin, TX (US)

(21) Appl. No.: 15/492,249

(22) Filed: Apr. 20, 2017

Related U.S. Application Data
(60) Provisional application No. 62/454,828, filed on Feb. 5, 2017.

(51) Int. Cl. H03K 19/00; H03K 19/20

(52) U.S. Cl. CPC H03K 19/0013; H03K 19/20

(57) ABSTRACT

A dynamic logic circuit includes a pull-up network coupled between a voltage supply and a dynamic node and receives a first input signal and a second input signal. A pull-down network is coupled between the dynamic node and a ground node and receives the first input signal and the second input signal. A pre-charge network is in parallel with the pull-up or pull-down network and pre-charges the dynamic node to a high or low voltage level prior to evaluation of the first and second input signals. The transistors in the pull-up network are substantially different in size than the transistors in the pull-down network.

### CROSS REFERENCE TO RELATED APPLICATIONS

This application claims benefit of provisional application number 62/454,828, entitled “CONTENTION-FREE DYNAMIC LOGIC”, naming Alexander W. Schaefer as inventor, filed Feb. 5, 2017, which application is incorporated herein by reference.

### BACKGROUND

### Description of the Related Art

Modern day processors require both high frequency operation for performance and low voltage operation to save power. To achieve high performance, traditional forms of dynamic logic have been used. Traditional dynamic logic, however requires a keeper circuit sized appropriately to avoid loss of correct pre-charge or pre-discharge values due to noise, leakage, and/or charge sharing and to avoid significant slowdown during evaluation.

FIG. 13 illustrates a traditional dynamic NOR structure 1300. The output node (dynamic conductor) 1301 is pre-charged to V_{DD} through p-channel metal oxide semiconductor (PMOS) transistor 1303 when the clock signal 1305 is low. When the clock signal rises to a high level, an evaluation phase determines the value of the output node 1301 based on input signals IN[0] and IN[1]. A high voltage level on the input signals IN[0] activates n-channel metal oxide semiconductor (NMOS) transistor 1307 causing the output node 1301 to be discharged to ground. Similarly, a high voltage level on the input signals IN[1] activates n-channel metal oxide semiconductor (NMOS) transistor 1309 causing the output node 201 to be discharged to ground. If the input signals are zero, the output node remains at the pre-charged voltage level as the path to ground is blocked with transistors 1307 and1309 turned off and a keeper transistor 1311 activates to keep the output node at the high voltage level. The gate of keeper transistor 1311 is coupled to the output of inverter 1313, which inverts the value of the output node 1301. However, the pull-down transistors 1307 and 1309 and the keeper transistor 1311 can be on at the same time, at least briefly as inputs change, causing contention between the keeper transistor and the pull-down transistors. The feedback keeper circuit in FIG. 13 can delay evaluation at lower voltages due to contention and may even fail to evaluate at very low voltages. During evaluation, the larger the keeper, the slower the switching time. Slowness during evaluation is exacerbated at low voltages. While traditional dynamic logic can stop working at very low voltages, standard, complementary CMOS logic scales well and continues to operate at very low voltages. Therefore, traditional dynamic logic is not suitable for designs that operate at very low voltages or designs that require scaling to lower voltages similar to that of standard, complementary CMOS logic.

### SUMMARY OF EMBODIMENTS OF THE INVENTION

Accordingly, in one embodiment an apparatus includes a pull-up network coupled between a voltage supply node and a dynamic node. The pull-up network is coupled to receive a first input signal and a second input signal. A pull-down network is coupled between the dynamic node and a ground node and is coupled to receive the first input signal and the second input signal. A pre-charge network is coupled to receive a pre-charge signal and is coupled to the dynamic node to pre-charge the dynamic node to a pre-charge voltage level prior to evaluation of the first and second input signals. The transistors in the pull-up network are substantially different in size than the transistors in the pull-down network.

In another embodiment a method includes pre-charging a dynamic node to a pre-charge voltage level responsive to a pre-charge signal prior to evaluation of a first input signal and a second input signal. A pull-up network receives the first input signal and the second input signal, the pull-up network being coupled between a voltage supply node and the dynamic node. A pull-down network receives first input signal and the second input signal and has transistors that are substantially different in size than transistors in the pull-up network.

In another embodiment an apparatus includes a first pull-up network coupled between a voltage supply node and a first dynamic node and coupled to receive a first input signal and a second input signal. A first pull-down network is coupled between the first dynamic node and a ground node and is coupled to receive the first input signal and the second input signal. A first pre-charge network is coupled in parallel with one of the first pull-up network and the first pull-down network. The pre-charge network is coupled to the dynamic node to pre-charge the dynamic node prior to evaluation of the first and second input signals. First transistors in the first pull-up network are substantially different in size than second transistors in the first pull-down network. A second pull-up network is coupled between the voltage supply node and a second dynamic node and is coupled to receive a third input signal and a fourth input signal, the third input signal being coupled to the first dynamic node. A second pull-down network is coupled between the second dynamic node and the ground node and is coupled to receive the third input signal and the fourth input signal. A second pre-charge network is coupled in parallel with one of the second pull-up network and the second pull-down network and is coupled to pre-charge the second dynamic node prior to evaluation of the third and fourth input signals. The third transistors in the second pull-up network are substantially different in size than fourth transistors in the second pull-down network.

### BRIEF DESCRIPTION OF THE DRAWINGS

The present invention may be better understood, and its numerous objects, features, and advantages made apparent to those skilled in the art by referencing the accompanying drawings.

FIG. 1 illustrates an embodiment of a dynamic logic circuit that includes a first dynamic logic circuit with a weak pull-up network that supplies a second dynamic logic circuit with a weak pull-down network.

FIG. 2 illustrates a dynamic logic circuit according to an embodiment that includes an inverter between dynamic logic stages.

FIG. 3 illustrates an embodiment of a dynamic NOR gate with a keeper sized pull-up network.

FIG. 4 illustrates a timing diagram associated with the dynamic NOR gate of FIG. 3.

FIG. 5 illustrates an embodiment of a dynamic NAND gate with a keeper sized pull-up network.

FIG. 6 illustrates an embodiment of a dynamic NOR gate with a keeper sized pull-down network.

FIG. 7 illustrates an embodiment of a dynamic NAND gate with a keeper sized pull-down network.

FIG. 8 illustrates an embodiment of a dynamic NOR gate with a keeper sized pull-up network and a footer transistor.

FIG. 9 illustrates an embodiment of a dynamic NAND gate with a keeper sized pull-up network and a footer transistor.

FIG. 10 illustrates an embodiment of a dynamic NOR gate with a keeper sized pull-down network and a header transistor.

FIG. 11 illustrates an embodiment of a dynamic NAND gate with a keeper sized pull-down network and a header transistor.

FIG. 12 illustrates an embodiment of a dynamic AND-OR-INVERT gate with a keeper sized pull-up network and a footer transistor.

FIG. 13 illustrates a traditional dynamic circuit.

The use of the same reference symbols in different drawings indicates similar or identical items.

### DETAILED DESCRIPTION

Embodiments described herein retain nearly all the benefits of traditional dynamic logic, while still scaling and operating at low voltages just as well as standard, complementary CMOS logic.

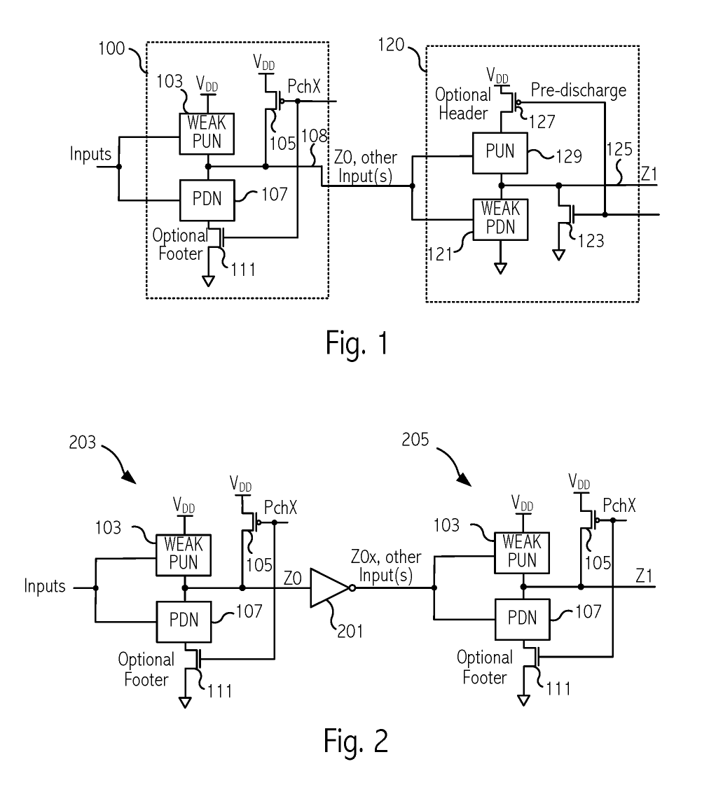

A standard complementary CMOS gate with a pull-up network (PUN) and a pull-down network (PDN) can be modified to create a contention-free dynamic logic gate of the same function. FIG. 1 illustrates the resulting modification as dynamic contention free logic gate 100. As shown in examples given herein, the logic gate 100 may be, e.g., a NOR gate, a NAND gate or other logic function. The first step in modifying a conventional CMOS gate is to shrink the pull-up network devices until they are as small as a typical keeper or keeper stack. As discussed further herein the typical keeper or keeper stack can be substantially smaller, e.g., between approximately 4 and 32 times smaller, than the transistors used in the non-keeper portion (e.g., the pull-down network 107 of FIG. 1). FIG. 1 shows the resulting weak pull-up network 103 after the modification. The modification to the standard device further includes adding a single pre-charge p-channel metal oxide semiconductor (PMOS) device 105 in parallel with the weak pull-up network 103. The pre-charge transistor 105 pre-charges the dynamic node 108 to a high voltage level. The control signal PchX deactivates the pre-charge transistor during the evaluate stage of the inputs. The transistors in the pull-down network 107 are substantially larger than the transistors in the pull-up keeper 103, e.g., by a size ratio of approximately 4 to approximately 32 times. The pull-down network 107 approximately matches the sizing that would be chosen in a standard, complementary CMOS logic gate.

The dynamic contention free logic gate 100 provides better performance than conventional CMOS logic because the input signal capacitance is smaller. Also, the dynamic contention free logic gate with the weak pull-up network provides a large beta ratio for speed. A beta ratio (Bn/Bp) is the ratio of relative strengths of n-channel devices to p-channel devices. In CMOS gates, having a beta ratio with Bn>Bp facilitates fast fall times and having a beta ratio with Bp >Bn facilitates fast rise times. The added pre-charge device 105 ensures good rise times even though the pull-up network is “weak” as compared to the pull-down network. The small-sized CMOS pull-up/pull-down keeper devices described herein only need be strong enough to retain the logic-high/low values provided by the pre-charge or pre-discharge devices and address issues such as noise, leakage, and/or charge sharing events. Note that as used herein the term “pre-charge” device may refer to a pull-up device that pre-charges the dynamic node to a high voltage level or the term “pre-charge” can be used more generally to refer to either a pull-up device or a pull-down device. The term “pre-discharge” device refers to a pull-down device that discharges the dynamic node to a low voltage level.

Note that a feedback keeper is not utilized in the dynamic contention free NOR gate 100. Rather than have a feedback keeper which can hurt performance at low voltages, the weak pull-up network is disabled while activating the pull-down network and vice versa. The disadvantage of using such an approach is power/area/complexity of adding in pre-charge devices and clocking for them. However, there may be no area penalty for adding the pre-charge device since the other devices in the weak pull-up (or pull-down) network are considerably smaller than devices in typical CMOS logic.

FIG. 1 also illustrates a pre-discharge/evaluate logic stage 120 that can be created from a conventional combinational gate in two steps. The first step shrinks the pull-down network devices until they are as small as a typical keeper or keeper stack would be (on the order of approximately four to approximately 32 times smaller than devices in pull-up network 129) to provide a weak pulldown network 121. The modification further adds a single pre-discharge n-channel metal oxide semiconductor (NMOS) device 123 in parallel with the weak pull-down network 121. The pre-discharge device 123 discharges the dynamic node 125 to a low voltage level prior to the evaluate portion of the cycle. Note that in FIG. 1, the charge signal PchX—˜Pre-Discharge signal (i.e., they are at opposite polarities). The input to pre-discharge/evaluate logic stage 120 includes Z0 (the output of stage 100) and potentially other inputs. If the output Z0 is the only input provided, stage 120 inverts the input.

With N to P ratios in current technology devices, N-P logic may be utilized where the design alternates pre-charge/evaluate logic stages with pre-discharge/evaluate logic stages. Referring again to FIG. 1, a pre-discharge/evaluate stage 120 follows pre-charge/evaluate stage 100.

Footer device 111 and header device 127 can be added to avoid contention if there is overlap between pre-charge/pre-discharge and the evaluation networks. With multiple stages, it may be difficult to control the timing of the charge and pre-discharge signals with respect to the evaluate cycle to avoid overlap.

Referring to FIG. 2, to avoid issues with noise on the dynamic nets given that the keepers (weak PDNs and weak PUNS) are not as able to prevent noise events as well as regular sized traditional static CMOS logic gates, and also to improve fanout, inverter 201 may be utilized between stages that are the same type of pull/up pull/down stage. FIG. 2 shows a dynamic logic device 203 coupled through inverter 201 to dynamic logic device 205. Both dynamic logic devices 203 and 205 utilize weak pull-up networks. The input to dynamic logic device 205 includes Z0x (the output of device 203 after being inverted in inverter 201) and potentially other inputs. If the output Z0x is the only input provided, device 205 functions as an inverter.

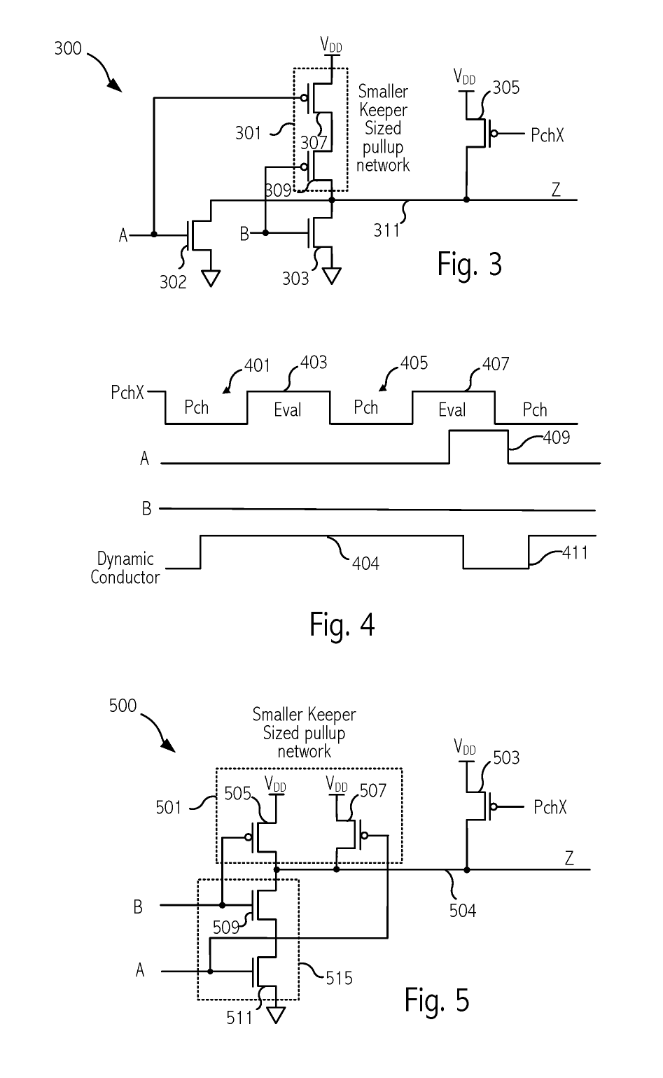

FIG. 3 illustrates a dynamic NOR circuit 300 according to an embodiment. The dynamic NOR circuit 300 receives inputs A and B. The dynamic NOR circuit utilizes a small keeper sized pull-up network 301 and a PMOS pre-charge transistor 305. The pull-up network includes transistors 307 and 309 that are sized substantially smaller than pull-down transistors 302 and 303.

FIG. 4 illustrates operation of the pre-charge/evaluate cycle utilized by the dynamic NOR circuit 300. A pre-charge signal PchX causes transistor 305 to pre-charge the dynamic node 311 (output node Z) to a high voltage level during pre-charge 401. During the evaluate portion of the cycle, the PchX signal is deasserted to cause transistor 305 to deactivate. During evaluation, with both inputs A and B at a low voltage, the dynamic conductor remains at a high voltage at 404. The next pre-charge cycle 405 pre-charges dynamic node 311 to a high voltage and the evaluate portion of the cycle 407, with the A input high at 409, results in the dynamic conductor being evaluated low at 411.

In the embodiment of FIG. 3, one should avoid the pre-charge signal PchX=0 while inputs A or B are high to avoid short circuit current. Short circuit current can be avoided if the data inputs (and the pre-charge signal) are clock-like to avoid such overlap.

FIG. 5 illustrates a contention free dynamic NAND gate 500 with inputs A and B. The dynamic NAND circuit utilizes a small keeper size pull-up network 501 and a PMOS pre-charge transistor 503 to pre-charge the dynamic node 504 to a high voltage. The pull-up network 501 includes transistors 505 and 507 that are sized substantially smaller than the transistors 509 and 511 in pull-down network 515.

In the embodiment of FIG. 5, one should avoid the pre-charge signal PchX=0 while inputs A and B are high to avoid short circuit current. Short circuit current can be avoided if the data inputs (and the pre-charge signal) are clock-like to avoid such overlap.

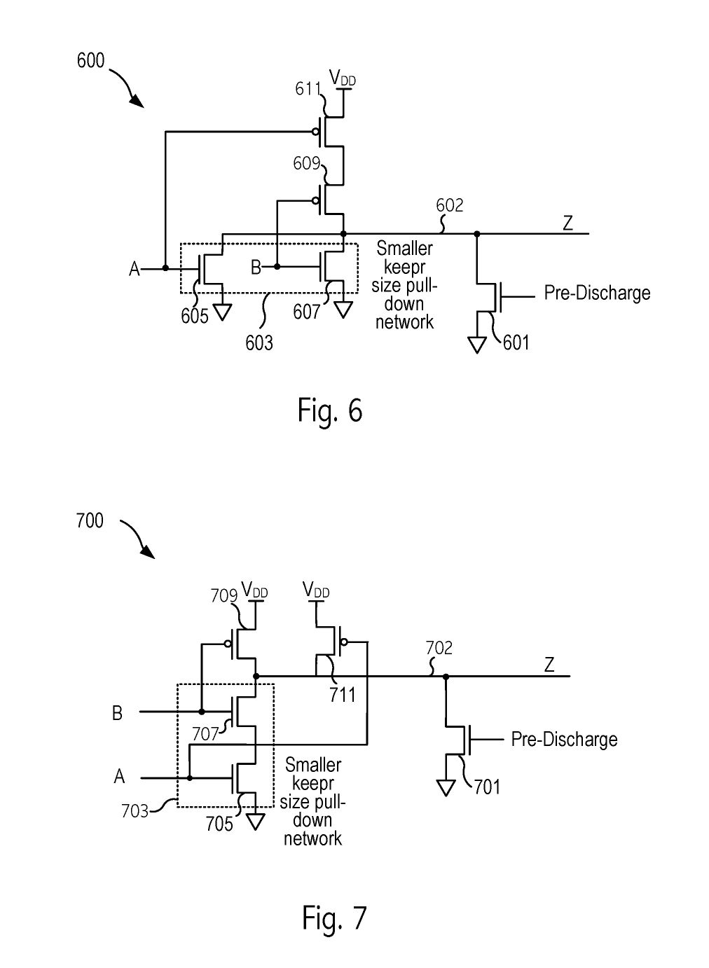

FIG. 6 illustrates a dynamic NOR circuit 600 that utilizes a pre-discharge transistor 601 to pull dynamic node 602 low prior to evaluation of inputs A and B. The dynamic NOR circuit 600 includes a smaller keeper sized pull-down network 603 having transistors 605 and 607 that are substantially smaller than the transistors 609 and 611 forming the pull-up network.

FIG. 7 illustrates a dynamic NAND circuit 700 that utilizes a pre-discharge transistor 701 to pull dynamic node 702 low prior to evaluation of inputs A and B. The dynamic NAND circuit 700 includes a smaller keeper sized pull-down network 703 having transistors 705 and 707 that are substantially smaller than the transistors 709 and 711 forming the pull-up network.

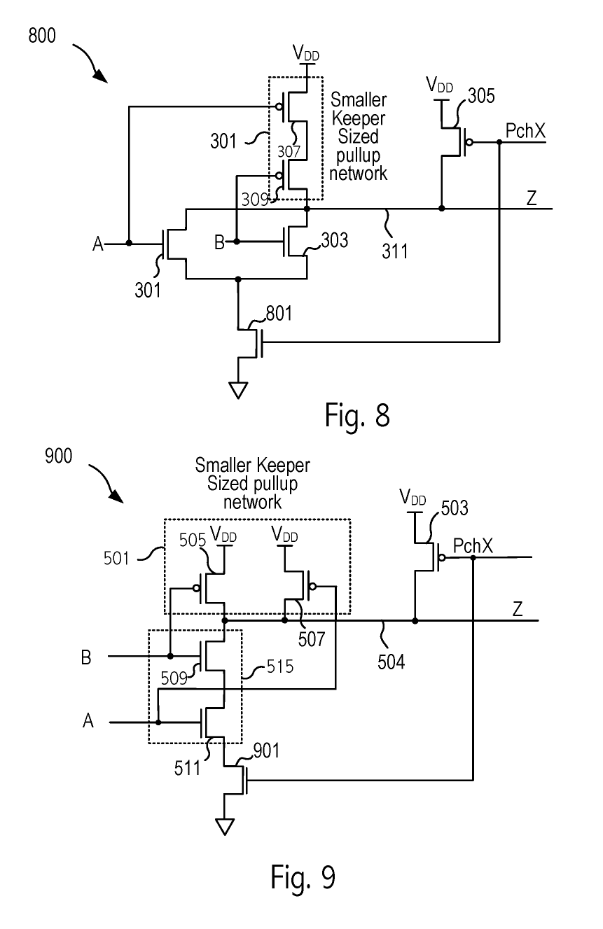

Referring to FIG. 8, dynamic NOR circuit 800 adds a footer device 801 to the dynamic NOR circuit 300 of FIG. 3 that helps avoid short circuit currents that could occur if inputs A or B are high while the pre-charge signal PchX is asserted (low).

Referring to FIG. 9, dynamic NAND circuit 900 adds a footer device 901 to the dynamic NAND circuit 500 of FIG. 5 that helps avoid short circuit currents that could occur if inputs A and B are high while the pre-charge signal PchX is asserted (low).

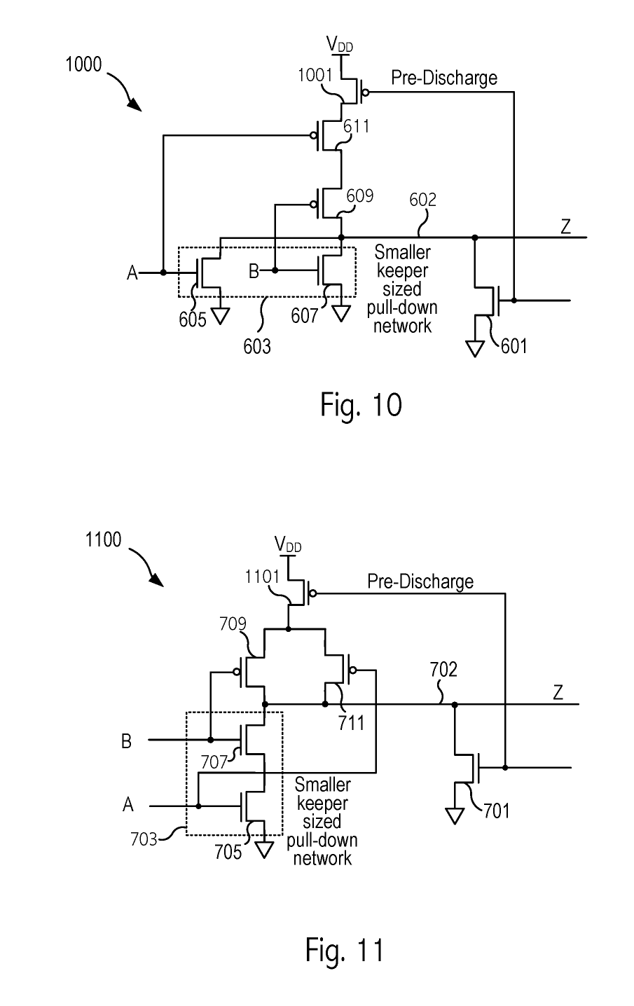

Referring to FIG. 10, dynamic NOR circuit 1000 adds a header device 1001 to the dynamic NOR circuit 600 of FIG. 6 that helps avoid short circuit currents that could occur if inputs A and B are low while the pre-discharge signal Pre-Discharge is asserted (high).

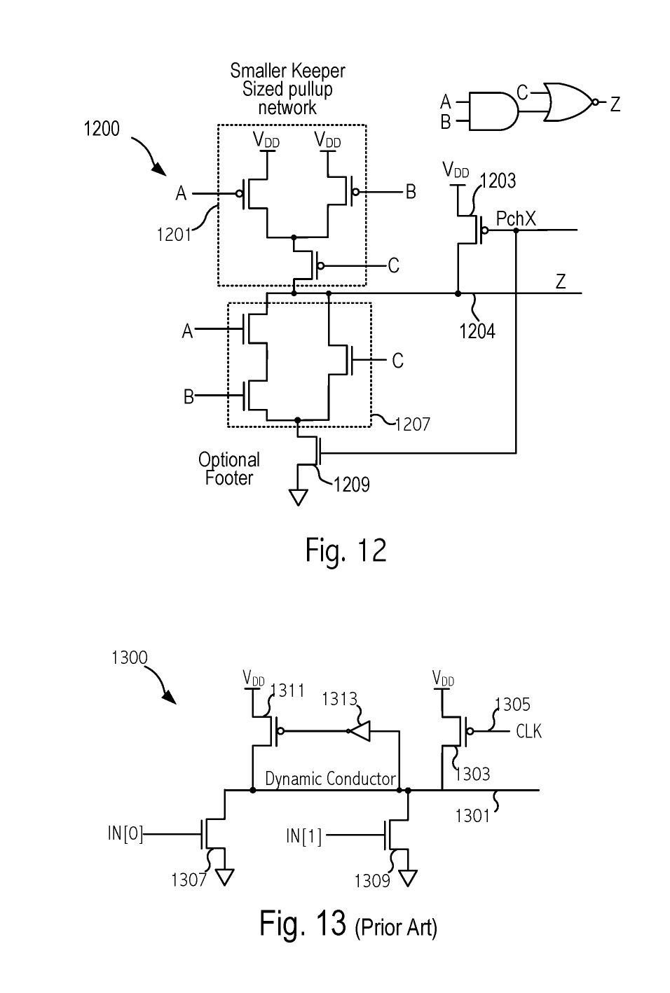

Referring to FIG. 11, dynamic NAND circuit 1100 adds a header device 1101 to the dynamic NAND circuit 700 of FIG. 7 that helps avoid short circuit currents that could occur if inputs A or B are low while the pre-discharge charge signal (Pre-Discharge) is asserted (high). Note that while two input dynamic logic devices are shown herein for ease of illustration and explanation, dynamic logic devices with more than two inputs, can readily incorporate the teachings herein to achieve dynamic logic gates with more than two input signals, by, e.g., having the same number of transistors in the pull-up and pull-down networks as there are inputs. While generic pull-up/pull-down structures have been shown in FIGS. 1 and 2 and NOR and NAND embodiments have been shown in other figures, contention free dynamic logic gates can be more complex such as the AND-OR-INVERT gate shown in FIG. 12. The AND-OR-INVERT gate 1200 includes a keeper sized pull-up network 1201, a pre-charge transistor 1203 that charges the dynamic node 1204 and a pull-down network 1207. The illustrated circuit includes an optional footer transistor 1209. The AND function receives the A,B inputs and the NOR function receives the output of the AND function and the C input.

The embodiments of dynamic logic devices described herein effectively allows for significant gate skewing of logic gates for fast evaluation while still maintaining fast pre-charge/pre-discharge switching by using single-stack pre-charge/pre-discharge devices. Gate skewing increases transistor size for the more critical timing path as compared to transistors on the less critical path to thereby achieve faster switching for the critical path. For example, skewed gates are used if one rising or falling edge is more timing critical than the other. The contention free dynamic logic described herein has less input capacitance for the logical inputs to the contention-free dynamic gates because the pull-up or pull-down devices are small. Also, the output node has less intrinsic loading with smaller devices. Gate skewing allows less short circuit current between pull-up/pull-down networks during switching events. As an example, consider an inverter. If the output is switching high to low, the NMOS device must sink current from the PMOS device while it is still active. If the PMOS device is small, a greater portion of the NMOS current can be used to discharge the output capacitance rather than the PMOS short circuit current resulting in faster switching. Gate skewing can be used, e.g., for a three input NAND gate with a 3-stack pull-down network and a three input single stack pull-up network. The stacked pull-down logic switches more slowly due to the stacking. Accordingly, the stacked devices may be increased in size to compensate for the slower switching. With contention-free dynamic logic, the gate skewing can be more extreme, e.g., the pull-down stack can be eight times the size of the pull-up logic as opposed to, e.g., a two to one size differential found in more conventional CMOS logic. Thus, the advantages of less input capacitance, less loading, smaller short circuit current, and less area can be enhanced with extreme gate skewing allowed by the contention free dynamic logic described herein. All this is achieved while avoiding contention between keepers and pull-up/pull-down networks by not using traditional keeper circuits with possible contention, which do not perform well, or at all, at lower voltages.

For multi-finger gates, the contention-free dynamic logic devices disclosed herein may be smaller than either complementary CMOS logic or dynamic logic with traditional keeper circuits. For example, a standard, complementary, 2-input, static CMOS gate (e.g. a NOR gate with four transistors) with 4 fingers per device would have 16 fingers total. In one embodiment, converting such a NOR gate to a contention-free dynamic logic gate described herein (see e.g., FIG. 3) would result in 8 fingers for the pulldown network (4 fingers per device), 2 fingers for the 2 devices in the pullup network (1 finger per device, which is keeper size), 4 fingers for the pre-charge device, and possibly less if pre-charge timing is not critical for a total of 14 fingers. A traditional dynamic gate using an inverter coupled to the dynamic node to control the keeper transistor would have 8 fingers for the pulldown network (4 fingers per device), 1 finger for the keeper, 2 fingers for the inverter, 4 fingers for the pre-charge device and possibly less if pre-charge timing is not critical for a total of 15 fingers. If a footer device or a header device is required, the contention-free dynamic logic gate described herein has more than the 14 fingers described above. Note that if the contention-free dynamic logic gates require headers/footers, the headers/footers would also be used in traditional dynamic logic circuits so the relative size difference between the contention-free dynamic logic circuits and the traditional dynamic logic circuits would remain. Thus, the contention-free dynamic logic gate described herein may be smaller than static CMOS logic and traditional dynamic logic.

As described herein, the smaller keeper sized transistors in the pull-up/pull-down networks are substantially smaller than the transistors in the conventionally sized pull-down/pull-up circuits. For example, referring to FIG. 3, in an embodiment, a typical size ratio of transistor 302 or 303 to the smaller keeper sized transistors 307 or 309 is in the range of 4:1 to 16:1. For dynamic circuits with single-stack PMOS keepers and single-stack NMOS pull-downs, the range could be 8:1 to 32:1. Such ranges are applicable, e.g., for a technology with PMOS strength approximately equal to NMOS strength.

The logic style described herein lends itself very well to array decoders where gates tend to be large to drive large fanout and data is usually clock-like to drive latch clocks or bitcell word lines. The clock-like data inputs allow for removal of header/footer devices.

Thus, embodiments for contention free dynamic logic circuits have been described. The description of the invention set forth herein is illustrative, and is not intended to limit the scope of the invention as set forth in the following claims. Other variations and modifications of the embodiments disclosed herein, may be made based on the description set forth herein, without departing from the scope of the invention as set forth in the following claims.

1. An apparatus comprising:
a pull-up network coupled between a voltage supply node and a first dynamic node and coupled to receive a first input signal and a second input signal;
a pull-down network coupled between the first dynamic node and a ground node and coupled to receive the first input signal and the second input signal;
a pre-charge network coupled to receive a pre-charge signal and coupled to the first dynamic node to pre-charge the first dynamic node to a pre-charge voltage level prior to evaluation of the first and second input signals;
wherein first transistors in the pull-up network are substantially different in size than second transistors in the pull-down network;
a second pull-up network coupled between the voltage supply node and a second dynamic node, the second pull-up network connected to the first dynamic node to receive an output signal on the first dynamic node as a third input signal and to receive a fourth input signal from another source;
a second pull-down network coupled between the second dynamic node and the ground node and coupled to receive the third input signal and the fourth input signal;
a second pre-charge network coupled to receive a second pre-charge signal and coupled to the second dynamic node to pre-charge the second dynamic node to a second pre-charge voltage level prior to evaluation of the third and fourth input signals, wherein one of the first and second pre-charge voltage levels is a high voltage level and the other of the first and second pre-charge voltage levels is a low voltage level;
wherein the first transistors of the pull-up network and third transistors of the second pull-up network are substantially different in size; and
wherein substantially different in size is smaller or larger by a factor of between approximately four and approximately thirty-two.

2. (canceled)

3. The apparatus as recited in claim 1 wherein substantially different is size is smaller or larger by a factor of between approximately four and approximately sixteen.

4. The apparatus as recited in claim 1 wherein the first transistors in the pull-up network are substantially smaller than the second transistors in the pull-down network and the pre-charge network includes a pull-up transistor coupled between the voltage supply node and the first dynamic node to pre-charge the first dynamic node to a high voltage level as the pre-charge voltage level.

5. The apparatus as recited in claim 4 further comprising a footer transistor coupled between the ground node and the pull-down network and the footer transistor is coupled to receive the pre-charge signal.

6. The apparatus as recited in claim 1 wherein fourth transistors of the second pull-down network are substantially smaller than the third transistors of the second pull-up network and the second pre-charge network includes a pull-down transistor coupled between the ground node and the second dynamic node to pre-charge the first dynamic node to the low voltage level as the pre-charge voltage level.

7. The apparatus as recited in claim 6 further comprising a header transistor coupled between the voltage supply node and the second pull-up network and the header transistor is coupled to receive the second pre-charge signal.

8. (canceled)

9. (canceled)

10. A method comprising:
pre-charging a dynamic node to a pre-charge voltage level responsive to a pre-charge signal prior to evaluation of a first input signal and a second input signal;
receiving the first input signal and the second input signal in a pull-up network coupled between a voltage supply node and the dynamic node; and
receiving the first input signal and the second input signal in a pull-down network having first transistors that are substantially different in size than second transistors in the pull-up network,
supplying an output signal on the dynamic node as a third input signal to a second pull-up network coupled between the voltage supply node and a second dynamic node;
supplying a fourth input signal to the second pull-up network;
supplying the third input signal and the fourth input signal to respective third transistors of a second pull-down network coupled between the second dynamic node and the ground node, the third transistors substantially smaller or substantially larger than the second transistors; and
pre-charging the second dynamic node to a second pre-charge voltage level prior to evaluation of the third and the fourth input signals;
wherein the first and second pre-charge voltage levels are different voltage levels; and
wherein substantially different in size is smaller or larger by a factor of between approximately four and approximately thirty-two.

11. (canceled)

12. The method as recited in claim 10 wherein substantially different in size is smaller or larger by a factor of between approximately four and approximately sixteen.

13. The method as recited in claim 10 further comprising pre-charging the dynamic node to a high voltage level through a pull-up transistor coupled between the voltage supply node and the dynamic node responsive to a first value of the pre-charge signal.

14. The method as recited in claim 13 further comprising:
turning off a footer transistor coupled between the ground node and the pull-down network responsive to the first value of the pre-charge signal;
activating the footer transistor responsive to a second value of the pre-charge signal; and
turning off the pull-up transistor responsive to the second value of the pre-charge signal.

15. The method as recited in claim 10 further comprising precharging the dynamic node to a low voltage level through a pull-down transistor coupled between the ground node and the dynamic node responsive to a first value of a pre-charge signal.

16. The method as recited in claim 15 further comprising turning off a header transistor coupled between the first voltage node and the pull-up network responsive to the first value of the pre-charge signal;
activating the header transistor responsive to a second value of the pre-charge signal; and
turning off the pull-down transistor responsive to the second value of the pre-charge signal.

17. (canceled)

18. (canceled)

19. The method as recited in claim 10 further comprising evaluating the first input signal and the second input signal with the pre-charge signal deasserted.

20. (canceled)
